(19) United States
(12) Patent Application Publication
(10) Pub. No.: US 2011/0315221 A1
(43) Pub. Date: Dec. 29, 2011

(54) METHODS FOR MAKING THIN FILM POLYCRYSTALLINE PHOTOVOLTAIC DEVICES USING ADDITIONAL CHEMICAL ELEMENT AND PRODUCTS THEREOF

(75) Inventors: Thomas HUNT, Oakland, CA (US); Mark TOPINKA, Berkeley, CA (US); Christopher RIVEST, Berkeley, CA (US)

(73) Assignee: Alion, Inc., Richmond, CA (US)

(21) Appl. No.: 12/973,581

(22) Filed: Dec. 20, 2010

Related U.S. Application Data
(60) Provisional application No. 61/288,772, filed on Dec. 21, 2009.
(60) Provisional application No. 61/288,775, filed on Dec. 21, 2009.

(51) Int. Cl. H01L 31/0272; H01L 31/18; H01L 31/0296

(52) U.S. Cl. 136/258; 438/94; 257/E31.016

(57) ABSTRACT

Method for making a photovoltaic device and structure thereof. The method includes providing a substrate including a glass layer, a first conductive layer on the glass layer, and a cadmium sulfide layer on the first conductive layer. Additionally, the method includes depositing one or more first materials on the cadmium sulfide layer. The one or more first materials include a first quantity of chemical element cadmium and a second quantity of chemical element tellurium. Moreover, the method includes performing a first thermal treatment to at least the first quantity of chemical element cadmium, the second quantity of chemical element tellurium, and a third quantity of chemical element chlorine, so that a polycrystalline layer composed of at least cadmium telluride is formed on the cadmium sulfide layer. Also, the method includes depositing one or more second materials on a surface of the polycrystalline layer.

### 1. CROSS-REFERENCES TO RELATED APPLICATIONS

This application claims priority to U.S. Provisional No. 61/288,772, filed Dec. 21, 2009, and U.S. Provisional No. 61/288,775, filed Dec. 21, 2009, both applications being commonly assigned and incorporated by reference herein for all purposes.

### 2. BACKGROUND OF THE INVENTION

The present invention is directed to material deposition and anneal. More particularly, the invention provides methods for depositing and annealing a material with assistance of another material. Merely by way of example, the invention has been applied to making photovoltaic devices. But it would be recognized that the invention has a much broader range of applicability.

Photovoltaics convert sunlight into electricity, providing a desirable source of clean energy. Some examples of current commercial photovoltaic solar cells are made of crystalline silicon and thin film (CdTe (Cadmium Telluride), CIGS (Copper-Indium-Gallium-Diselenide), or amorphous silicon) as well as polymer (P3HT/PCBM (poly(3-hexylthiophene)/phenyl-C61-butyric acid methyl ester) and derivatives).

For example, photovoltaic solar cells in a thin-film polycrystalline solar panel each are composed of a continuous film of crystals. Some conventional methods for creating continuous polycrystalline films include vacuum deposition methods such as sputtering, evaporation, or vapor transport deposition, and non-vacuum deposition methods such as atomized or ultrasonic spray, droplet-on-demand printing, and continuous liquid film coating. The continuous liquid film coating can be slot coating, doctor blade, roller coating, bath, or dip coating.

Often, material for non-vacuum deposition is prepared as particles suspended in fluid, or as precursor chemicals suspended in fluid. After a film is deposited either as precursor in fluid or as particles in fluid, the carrier fluid may be removed, for example, by evaporation. Subsequently, in order to form a continuous polycrystalline film from chemical or particle precursors, heat treatment usually is required for grain growth. In comparison with vacuum deposition methods, non-vacuum deposition methods usually offer cost advantages in manufacturing due to reduced equipment, energy, and maintenance costs. But the continuous films of crystals formed with these non-vacuum deposition methods often have only limited photovoltaic performance.

Hence it is highly desirable to improve fabrication techniques for photovoltaic devices.

### 3. BRIEF SUMMARY OF THE INVENTION

The present invention is directed to material deposition and anneal. More particularly, the invention provides methods for depositing and annealing a material with assistance of another material. Merely by way of example, the invention has been applied to making photovoltaic devices. But it would be recognized that the invention has a much broader range of applicability.

According to one embodiment, a method for making a photovoltaic device includes providing a substrate including a glass layer, a first conductive layer on the glass layer, and a cadmium sulfide layer on the first conductive layer. Additionally, the method includes depositing one or more first materials on the cadmium sulfide layer. The one or more first materials include a first quantity of chemical element cadmium and a second quantity of chemical element tellurium. Moreover, the method includes performing a first thermal treatment to at least the first quantity of chemical element cadmium, the second quantity of chemical element tellurium, and a third quantity of chemical element chlorine, so that a polycrystalline layer composed of at least cadmium telluride is formed on the cadmium sulfide layer. Also, the method includes depositing one or more second materials on a surface of the polycrystalline layer. The one or more second materials including a fourth quantity of chemical element chlorine. Additionally, the method includes performing a second thermal treatment to at least the one or more second materials so that at least a first part of the fourth quantity of chemical element chlorine diffuses into the polycrystalline layer, removing at least a second part of the fourth quantity of chemical element chlorine from the surface of the polycrystalline layer, and forming a second conductive layer on the polycrystalline layer composed of at least cadmium telluride.

According to another embodiment, a method for making a photovoltaic device includes providing a substrate including a glass layer, a first conductive layer on the glass layer, and a cadmium sulfide layer on the first conductive layer. Additionally, the method includes depositing a first liquid ink composed of at least one or more cadmium telluride particles and a first cadmium chloride material in a first solvent, and performing a first thermal treatment to at least the one or more cadmium telluride particles and the first cadmium chloride material, so that a polycrystalline layer composed of at least cadmium telluride is formed on the cadmium sulfide layer. Moreover, the method includes depositing a second liquid ink composed of at least a second cadmium chloride material in a second solvent, and performing a second thermal treatment to at least the second cadmium chloride material so that at least a first part of the second cadmium chloride material diffuses into the polycrystalline layer. Also, the method includes removing at least a second part of the second cadmium chloride material from the surface of the polycrystalline layer, and forming a second conductive layer on the polycrystalline layer composed of at least cadmium telluride.

According to yet another embodiment, a photovoltaic device includes a substrate including a glass layer, a first conductive layer on the glass layer, and a cadmium sulfide layer on the first conductive layer. Additionally, the photovoltaic device includes a polycrystalline layer composed of at least cadmium telluride on the cadmium sulfide layer. The polycrystalline layer is doped with chemical element chlorine. Also, the photovoltaic device includes a second conductive layer on the polycrystalline layer, and an encapsulation layer on the second conductive layer. The photovoltaic device is characterized by a photovoltaic conversion efficiency that is greater than 9% under standard test conditions, an open circuit voltage that is greater than 750 mV, and a short circuit current that is greater than 20 mA/cm².

According to yet another embodiment, a photovoltaic device includes a substrate including a glass layer, a first conductive layer on the glass layer, and a cadmium sulfide layer on the first conductive layer. Additionally, the photovoltaic device includes a polycrystalline layer composed of at least cadmium telluride on the cadmium sulfide layer. The polycrystalline layer is doped with chemical element chlorine. Moreover, the photovoltaic device includes a second conductive layer on the polycrystalline layer, and an encapsulation layer on the second conductive layer. The polycrystalline layer includes a first surface and a second surface, and the polycrystalline layer is characterized by a porosity. The porosity of the polycrystalline layer close to the first surface is larger than the porosity of the polycrystalline layer close to the second surface.

Many benefits are achieved by way of the present invention over conventional techniques. Certain embodiments of the present invention use a flux to effectively reduce the temperature required for a continuous polycrystalline film to form from chemical or particle precursors, and hence improve grain growth or recrystallization during the heat treatment. Some embodiments of the present invention introduce one or more additional chemical elements to the CdTe film and improve electrical characteristics of the film. For example, the carrier recombination in the CdTe film is reduced by passivating grain boundaries. In another example, the carrier concentration is improved by doping the CdTe film. In yet another example, the quantity of the one or more additional chemical elements that diffuse into the CdTe film is controlled by super-saturating the film surface with a high concentration of the desired chemical elements, driving in some quantity of the chemical elements from the surface with a heat treatment, and subsequently washing away the excessive quantity that remains on the film surface.

Certain embodiments of the present invention provide a polycrystalline CdTe layer with improved electrical and optical properties and a thin-film CdTe solar panel with improved conversion efficiency. For example, the annealing of CdTe benefits from a flux of cadmium chloride. In another example, with the addition of cadmium chloride flux, the annealed CdTe particles form larger grains with better electrical and optical properties. Some embodiments of the present invention further improve electrical properties of the CdTe film by driving one or more additional chemical elements, such as chlorine, into the film by diffusion.

Depending upon embodiment, one or more of these benefits may be achieved. These benefits and various additional objects, features and advantages of the present invention can be fully appreciated with reference to the detailed description and accompanying drawings that follow.

### 4. BRIEF DESCRIPTION OF THE DRAWINGS

FIG. 1 is a simplified diagram showing a method for making a photovoltaic device according to one embodiment of the present invention.

FIG. 2 is a simplified diagram showing the process for providing a substrate as part of the method for making a photovoltaic device according to one embodiment of the present invention.

FIG. 3 is a simplified diagram showing the process for depositing one or more first materials and the process for performing a first thermal treatment as parts of the method for making a photovoltaic device according to one embodiment of the present invention.

FIG. 4 is a simplified diagram showing the process for depositing one or more second materials, the process for performing a second thermal treatment, and the process for removing remaining one or more second materials as parts of the method for making a photovoltaic device according to one embodiment of the present invention.

FIG. 5 is a simplified diagram showing the process for completing fabrication of a photovoltaic device as part of the method for making a photovoltaic device according to one embodiment of the present invention.

FIG. 6 is a simplified diagram showing the effect of certain processes on the photovoltaic device that is made by the method for making a photovoltaic device according to one embodiment of the present invention.

FIG. 7 is a simplified diagram showing a porous CdTe layer according to one embodiment of the present invention.

### 5. DETAILED DESCRIPTION OF THE INVENTION

The present invention is directed to material deposition and anneal. More particularly, the invention provides methods for depositing and annealing a material with assistance of another material. Merely by way of example, the invention has been applied to making photovoltaic devices. But it would be recognized that the invention has a much broader range of applicability.

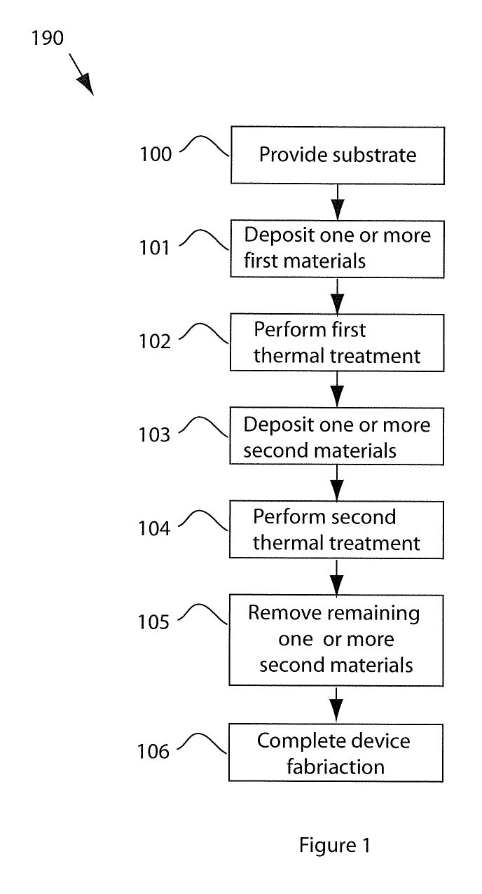

FIG. 1 is a simplified diagram showing a method for making a photovoltaic device according to one embodiment of the present invention. This diagram is merely an example, which should not unduly limit the scope of the claims. One of ordinary skill in the art would recognize many variations, alternatives, and modifications. The method 190 for making a photovoltaic device includes a process 100 for providing a substrate, a process 101 for depositing one or more first materials, a process 102 for performing a first thermal treatment, a process 103 for depositing one or more second materials, a process 104 for performing a second thermal treatment, a process 105 for removing remaining one or more second materials, and a process 106 for completing device fabrication. For example, the first thermal treatment and the second thermal treatment are each an anneal process.

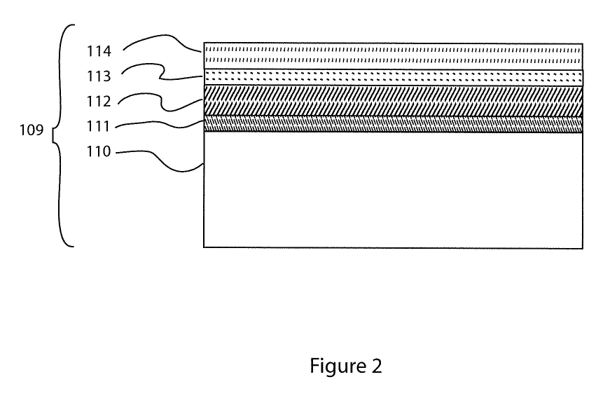

At the process 100, a substrate is provided for depositing a cadmium telluride (CdTe) layer on the substrate. FIG. 2 is a simplified diagram showing the process 100 for providing a substrate as part of the method 190 for making a photovoltaic device according to one embodiment of the present invention. This diagram is merely an example, which should not unduly limit the scope of the claims. One of ordinary skill in the art would recognize many variations, alternatives, and modifications.

As shown in FIG. 2, a substrate 109 is provided for depositing a CdTe layer on the substrate according to one embodiment. For example, the substrate 109 includes a glass layer that is coated with cadmium sulfide (CdS). In another example, the substrate 109 includes a glass layer 110, a diffusion barrier layer 111, a transparent conductive layer 112, a buffer layer 113, and a CdS layer 114.

In one embodiment, the glass layer 110 is composed of soda-lime glass with thickness ranging from 2 mm to 4 mm. In another embodiment, the glass layer 110 is coated with the diffusion barrier layer 111, which is composed of silicon dioxide. For example, the diffusion barrier layer 111 has sufficient thickness to block elemental diffusion (e.g., sodium diffusion) from the surface of the glass layer 110 during at least the thermal treatments 102 and 104 and/or during many years in the field. In another example, the diffusion barrier layer 111 is at least 10-nm thick, such as being 100-nm thick.

In yet another embodiment, on top of the diffusion barrier 110, there is the transparent conductive layer 112. For example, the transparent conductive layer 112 is composed of one or more transparent conductive oxides, such as tin oxide doped with fluorine, zinc oxide doped with fluorine, and/or cadmium stannate doped with fluorine. In another example, the transparent conductive layer 112 has a sheet resistance that is less than 15 ohms per square or less than 10 ohms per square. In yet another example, the transparent conductive layer 112 is at least 80% or 90% transmissive to light that ranges from 400 nm to 1000 nm in wavelength.

As shown in FIG. 2, the buffer layer 113 is located on top of the transparent conductive layer 112 according to one embodiment. For example, the buffer layer 113 has a higher sheet resistance than the transparent conductive layer 112. In another example, the buffer layer 113 is composed of one or more conductive oxides (e.g., un-doped tin oxide) that are less conductive than the one or more conductive oxides (e.g., fluorine-doped tin oxide) that form the transparent conductive layer 112. In yet another example, the buffer layer 113 has a thickness of more than 20 nm thick, such as ranging from 75 nm to 400 nm.

According to another embodiment, on top of the buffer layer 113, there is the CdS layer 114. For example, the CdS layer 114 is used as the n-type semiconductor region in the photovoltaic device (e.g., a CdS—CdTe solar cell). In another example, the CdS layer 114 is thin enough to allow significant transmission of blue light but not too thin to cause shunts in the photovoltaic device. In one embodiment, the CdS layer 114 has a thickness larger than 40 nm and less than 400 nm. In another embodiment, the CdS layer 114 has a thickness that is determined by manufacturing tolerances and by the amount of sulfur diffusion into the CdTe during subsequent fabrication processes.

At the process 101, one or more first materials are deposited on the substrate. For example, the one or more first materials include one or more precursors for forming the cadmium telluride (CdTe) layer on the substrate, and one or more fluxes. In one embodiment, the one or more precursors include the chemical element of cadmium (Cd) and the chemical element of tellurium (Te). In another example, the one or more fluxes include the chemical element of chlorine (Cl).

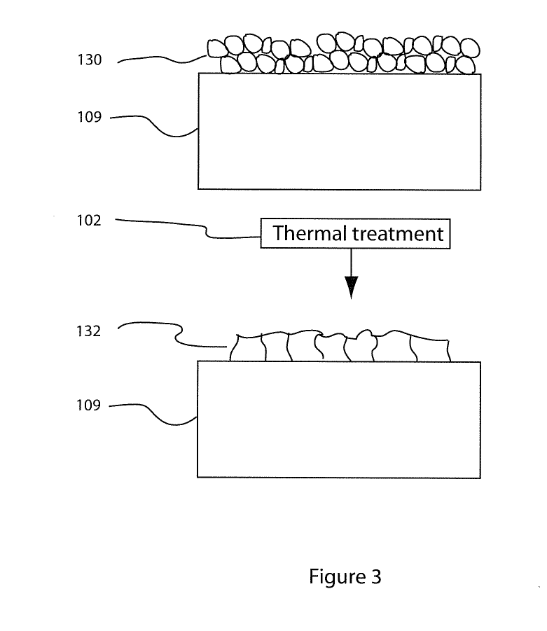

FIG. 3 is a simplified diagram showing the process 101 for depositing one or more first materials and the process 102 for performing a first thermal treatment as parts of the method 190 for making a photovoltaic device according to one embodiment of the present invention. This diagram is merely an example, which should not unduly limit the scope of the claims. One of ordinary skill in the art would recognize many variations, alternatives, and modifications.

As shown in FIG. 3, one or more liquid inks are deposited onto the substrate 109 according to one embodiment. For example, the one or more liquid inks have one or more Cd-containing materials, one or more Te-containing materials, and one or more Cl-containing materials in one or more solvents. In another example, the one or more liquid inks have CdTe particles and one or more Cl-containing materials (e.g., dissolved cadmium chloride) in one or more solvents. In yet another example, cadmium chloride (CdCl₂) is mixed into a liquid ink that contains the CdTe particles at a concentration of 1-20% of the mass of the CdTe particles in the ink, or at a concentration of 5-15% of the mass of the CdTe particles in the ink.

According to another embodiment, after the deposition, the one or more solvents in the one or more inks are evaporated, leaving a layer 130 of particles on the substrate 109. For example, the layer 130 includes the one or more Cd-containing materials, the one or more Te-containing materials, and the one or more Cl-containing materials (e.g., the CdCl₂ material). In another example, the layer 130 includes the CdTe particles and the one or more Cl-containing materials (e.g., the CdCl₂ material). In yet another example, the CdCl₂ material in the layer 130 has a mass that is between 1-10% of the mass of the layer 130.

As discussed above and further emphasized here, FIG. 3 is merely an example, which should not unduly limit the scope of the claims. One of ordinary skill in the art would recognize many variations, alternatives, and modifications. In one embodiment, one or more liquid inks that include the Cd-containing particles and the Te-containing particles suspended in one or more solvents, or a liquid ink that includes the CdTe particles suspended in a solvent, is deposited onto the substrate 109. Additionally, for example, before this deposition, another liquid ink that includes the one or more Cl-containing materials (e.g., the dissolved CdCl₂) in another solvent is deposited onto the substrate 109, or after this deposition, another liquid ink that includes the one or more Cl-containing materials (e.g., the dissolved CdCl₂) in another solvent is deposited onto the layer of the Cd-containing particles and the Te-containing particles or onto the layer of the CdTe particles.

In another embodiment, the liquid ink that includes the CdCl₂ material is deposited before or after the deposition of the liquid ink that includes the CdTe particles. For example, the liquid ink that includes the CdCl₂ material has a concentration of CdCl₂ that ranges from 0.1 molar to 1 molar. In another example, the deposited layer of CdCl₂ has a mass that is between 1-20% of the mass of the deposited layer of CdTe particles. In yet another example, the liquid ink that includes the CdCl₂ material is sprayed, printed, dip coated, or roller coated onto the dried or wet layer of CdTe particles, and the solvent for the CdCl₂ material includes water, alcohol, and/or ethylene glycol.

Returning to FIG. 1, at the process 102, a first thermal treatment is performed. Referring to FIG. 3, the layer 130 is annealed to become a layer 132 according to one embodiment. For example, as described above, the layer 130 includes the one or more Cd-containing materials, the one or more Te-containing materials, and the one or more Cl-containing materials (e.g., the CdCl₂ material), or the layer 130 includes the CdTe particles and the one or more Cl-containing materials (e.g., the CdCl₂ material). In another example, the layer 130 includes a layer of CdCl₂, and another layer of Cd-containing particles and Te-containing particles or of CdTe particles. In yet another example, the layer 132 is a continuous polycrystalline CdTe layer with a thickness ranging from 0.5 to 5 μm or ranging from 2 μm to 4 μm.

In one embodiment, the first thermal treatment is carried out at the atmospheric pressure. In another embodiment, the first thermal treatment melts the particles of the layer 130. For example, the first thermal treatment is performed at a temperature ranging from 450° C. to 650° C., or ranging from 500° C. to 600° C. In another example, the first thermal treatment is performed for a period of time ranging from 5 minutes to 1 hour or from 10 minutes to 30 minutes.

In yet another embodiment, the layer 130 includes the CdTe particles and the CdCl₂ material. For example, before the first thermal treatment, the CdCl₂ material in the layer 130 has a mass that is between 1-10% of the mass of the layer 130. In another example, after the first thermal treatment, less than 10% of the CdCl₂ material that was previously in the layer 130 before the first thermal treatment remains in the layer 130. In yet another example, some of the CdCl₂ material that was previously in the layer 130 before the first thermal treatment exits the layer 130 as vapor during the first thermal treatment.

As discussed above and further emphasized here, FIGS. 1 and 3 are merely examples, which should not unduly limit the scope of the claims. One of ordinary skill in the art would recognize many variations, alternatives, and modifications. In one embodiment, the processes 101 and 102 are replaced by the following two processes. First, as an example, one or more liquid inks that include the Cd-containing particles and the Te-containing particles suspended in one or more solvents, or a liquid ink that includes the CdTe particles suspended in a solvent, is deposited onto the substrate 109 as the layer 130. Then, as another example, a first thermal treatment is performed during which a gas-phase flux of one or more Cl-containing materials (e.g., a gas-phase flux of CdCl₂ or a flux of Chlorine gas) is delivered to the layer 130. According to one embodiment, the atmosphere around the layer 130 is at a temperature ranging from 450° C. to 650° C. or ranging from 500° C. to 600° C. According to another embodiment, the CdCl₂ vapor pressure for the gas-phase flux of CdCl₂ is maintained between 1-100 torr or between 1-10 torr during at least a portion of the first thermal treatment.

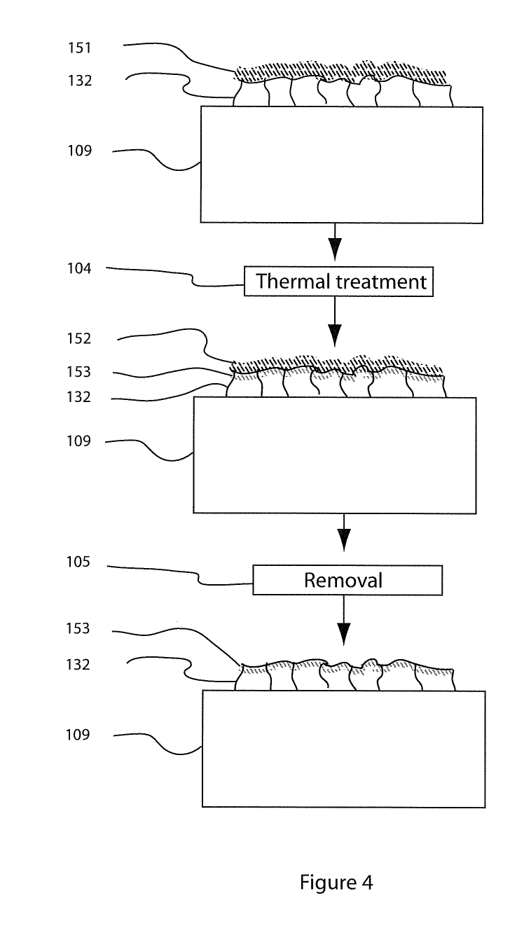

Returning to FIG. 1, at the process 103, one or more second materials are deposited. FIG. 4 is a simplified diagram showing the process 103 for depositing one or more second materials, the process 104 for performing a second thermal treatment, and the process 105 for removing remaining one or more second materials as parts of the method 190 for making a photovoltaic device according to one embodiment of the present invention. This diagram is merely an example, which should not unduly limit the scope of the claims. One of ordinary skill in the art would recognize many variations, alternatives, and modifications.

As shown in FIG. 4, a liquid ink is deposited onto the layer 132 according to one embodiment. For example, as described above, the layer 132 is a continuous polycrystalline CdTe layer. In another example, the liquid ink that includes one or more Cl-containing materials (e.g., dissolved CdCl₂) in a solvent is deposited onto the layer 132. In yet another example, the liquid ink that includes the CdCl₂ material is sprayed, printed, dip coated, or roller coated onto the layer 132.

According to another embodiment, after the deposition, the solvent in the liquid ink is evaporated, leaving a layer 151 of particles on the layer 132. For example, the layer 151 is a thin solid film composed of the one or more Cl-containing materials (e.g., the CdCl₂ material). In another example, the one or more Cl-containing materials (e.g., the CdCl₂ material) are delivered to the surface of the layer 132 in a sufficiently high concentration that the one or more Cl-containing materials serve as a source for diffusion during the second thermal treatment.

Returning to FIG. 1, at the process 104, a second thermal treatment is performed. In one embodiment, the second thermal treatment is carried out at the atmospheric pressure. In another embodiment, as shown in FIG. 4, the second thermal treatment drives by diffusion the chemical element of chloride from the layer 151 into the layer 132 to form a doped sub-layer 153 in the layer 132. For example, the second thermal treatment is performed at a temperature ranging from 150° C. to 450° C., or ranging from 300° C. to 450° C. In another example, the second thermal treatment is performed for a period of time ranging from 1 minute to 30 minutes.

At the process 105, the remaining one or more second materials are removed. As shown in FIG. 4, after the second thermal treatment, part of the layer 151 remains on the surface of the layer 132 and is called the layer 152. In one embodiment, the layer 152 is at least partially removed (e.g., washed and/or etched away) during the process 105. In another embodiment, the removal is performed by washing or etching away at least parts of the layer 152 without damaging the polycrystalline layer 132.

For example, the washing away of the layer 152 includes a dip or spray using one or more aqueous or organic solvents that dissolve and/or suspend at least parts of the layer 152 from the surface of the layer 132. In another example, the washing away of the layer 152 includes several stages (e.g., three stages) for successive dilution of the remaining particles of the layer 152 and for reduction of the liquid waste generated during the washing process. In yet another example, the washing away of the layer 152 uses a solvent at an elevated temperature, such as 40° C., to increase the rate that the layer 152 dissolves into the solvent.

In one embodiment, the one or more Cl-containing materials (e.g., the CdCl₂ material) that remain inside the layer 132 after the process 105 are sufficient to passivate the grain boundaries or to dope the CdTe layer 132. In another embodiment, the one or more Cl-containing materials (e.g., the CdCl₂ material) that remain inside of the layer 132 after the process 105 are no more than 10% of the film mass of the layer 132, less than 1% of the film mass of the layer 132, or as little as 1 part per million of film mass of the layer 132.

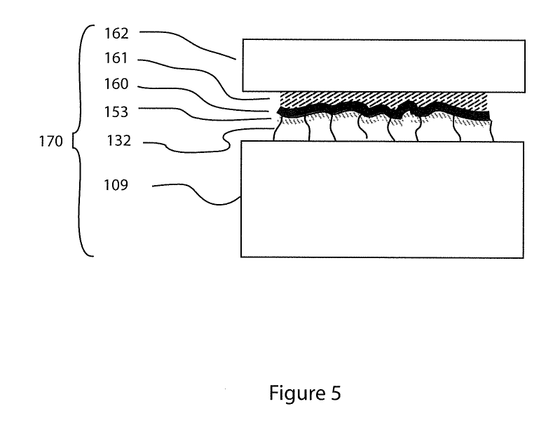

Returning to FIG. 1, at the process 106, the fabrication of the photovoltaic device is completed with, for example, one or more thin film photovoltaic processing steps. FIG. 5 is a simplified diagram showing the process 106 for completing fabrication of a photovoltaic device 170 as part of the method 190 for making a photovoltaic device according to one embodiment of the present invention. This diagram is merely an example, which should not unduly limit the scope of the claims. One of ordinary skill in the art would recognize many variations, alternatives, and modifications. For example, the photovoltaic device 170 is a photovoltaic cell, e.g., a solar cell.

As shown in FIG. 5, an ohmic contact layer 160 is formed on the CdTe layer 132, which also includes the doped sub-layer 153. In one embodiment, one or more materials that can form an ohmic contact to CdTe and have high conductivity are used for making the layer 160. For example, the ohmic contact layer 160 has a sheet resistance that is less than 10 ohms per square or less than 2 ohms per square. In another example, the ohmic contact layer 160 includes one or more metallic layers and/or one or more carbon/organics and metal layers. In yet another example, the ohmic contact layer 160 has a thickness greater than 100 nm or greater than 300 nm. In yet another example, the ohmic contact layer 160 is deposited by spraying, dip coating, roller coating, evaporation, and/or sputtering methods.

Additionally, according to certain embodiments, one or more laser scribes are used to pattern the various layers of the photovoltaic device to produce one or more individual cells on a glass substrate that are interconnected in serial or parallel, before or after the ohmic contact layer 160 is formed. Also, as shown in FIG. 5, the completed photovoltaic device 170 is encapsulated with a polymer sheet 161 or with the polymer sheet 161 and another back sheet 162 (e.g., a glass sheet, a metal sheet, or a layered back sheet) according to certain embodiments.

Moreover, according to some embodiments, one or more conductive buss bars are applied to the transparent conductive layer (e.g., the transparent conductive layer 112 of the substrate 109) and/or to the ohmic contact layer 160 to collect one or more photocurrents from the interconnected cells. For example, the one or more buss bars exit the encapsulation for the photovoltaic device 170 into one or more junction boxes and/or into one or more edge connectors for one or more electrical connections.

As discussed above and further emphasized here, FIGS. 1-5 are merely examples, which should not unduly limit the scope of the claims. One of ordinary skill in the art would recognize many variations, alternatives, and modifications.

In one embodiment, the one or more Cl-containing materials (e.g., the CdCl₂ material) are replaced by any other types of particles that can lower the temperature required to melt the CdTe particles into a continuous polycrystalline layer during the first thermal treatment. For example, the first thermal treatment is performed at a temperature that is compatible with a low-cost soda-lime glass substrate and with other layers on the substrate. In another example, the first thermal treatment is performed for a period of time that is sufficient for grain growth (e.g., longer than 5 minutes) but short enough for low manufacturing cost (e.g., shorter than 1 hour).

In another embodiment, the one or more second materials are used to improve the electrical properties of the continuous polycrystalline CdTe layer 132. For example, the one or more second materials include the chemical element of chloride and/or the chemical element of oxygen. In another example, the second thermal treatment is performed for a period of time that is sufficient to drive in the chemical element of chloride and/or the chemical element of oxygen by diffusion (e.g., longer than 1 minute) but short enough for low manufacturing cost (e.g., shorter than 30 minutes). In yet another embodiment, the encapsulation of the completed photovoltaic device 170 is used to improve the durability of the device 170.

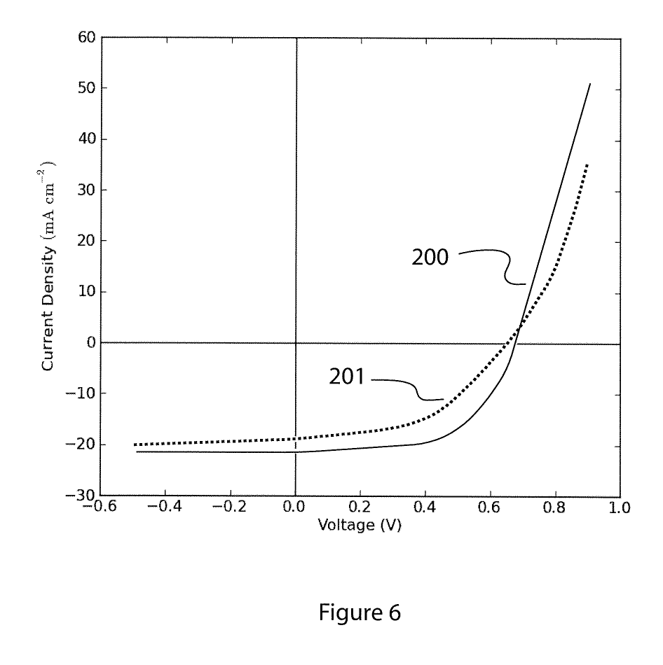

FIG. 6 is a simplified diagram showing the effect of processes 103 and 104 on the photovoltaic device 170 that is made by the method 190 according to one embodiment of the present invention. This diagram is merely an example, which should not unduly limit the scope of the claims. One of ordinary skill in the art would recognize many variations, alternatives, and modifications. The curve 200 represents current density as a function of voltage for the photovoltaic device 170 fabricated by the method 190 that includes the processes 103 and 104, and the curve 201 represents current density as a function of voltage for a photovoltaic device fabricated without the processes 103 and 104.

In one embodiment, the photovoltaic device fabricated without the processes 103 and 104 has weaker photovoltaic performance in comparison with the photovoltaic device 170, which is fabricated by the method 190 that includes the processes 103 and 104. For example, the photovoltaic device fabricated without the processes 103 and 104 has a photovoltaic conversion efficiency that is less than 7% under standard test conditions (STC), an open circuit voltage that is less than 700 mV, and a short circuit current that is less than 19 mA/cm². In another example, the photovoltaic device 170 fabricated by the method 190 that includes the processes 103 and 104 has an STC photovoltaic conversion efficiency that is greater than 9%, an open circuit voltage that is greater than 750 mV, and a short circuit current that is greater than 20 mA/cm². In yet another example, the standard test conditions (STC) include 25° C. cell temperature and 1000 watts per square meter radiation with an AM1.5G spectrum defined by ASTM G173-03.

In another embodiment, the photovoltaic device 170 fabricated by the method 190 that includes the processes 103 and 104 continues to produce power even after being exposed to various weather conditions. For example, after 20 years of use in the field, the encapsulated photovoltaic device 170 produces at least 80% or 90% of the power that it produces immediately after completion of device fabrication. In another example, after accelerated lifetime testing that includes 1,000 hours of damp heat exposure at 85° C. with 85% humidity, or after 500 thermal cycles from −40° C. to +90° C., the encapsulated photovoltaic device 170 produces at least 85% or 90% of the power that it produces immediately after completion of device fabrication.

Some embodiments of the present invention provide a method for converting a precursor film into a continuous polycrystalline semiconductor film for a photovoltaic device using flux and heat treatment at atmospheric pressure. For example, the flux is deposited on the substrate, dissolved in a fluid carrier, simultaneously with the precursor film. In another example, the flux is deposited on the substrate, dissolved in a fluid carrier, before the precursor film is deposited. In yet another example, the flux is deposited on the substrate, dissolved in a fluid carrier, after the precursor film is deposited. In yet another example, the flux is deposited on the substrate via vapor during heat treatment. In yet another example, the flux content of the film is 1-20% of the mass of the film before heat treatment, and less than 10% of the flux content that was in the film before the heat treatment remains in the film after the heat treatment.

Certain embodiments provide a method for improving electrical properties of a polycrystalline semiconductor film by diffusion of elements sourced at the film surface with heat treatment at atmospheric pressure. For example, the source for the elements is delivered to the film surface dissolved in a fluid carrier. In another example, at least some of the elements remain at the film surface, and are subsequently washed away before completion of the photovoltaic device. In yet another example, the elements are the same as the flux used for grain growth with an earlier heat treatment process. In yet another example, the later heat treatment process is the same as the earlier heat treatment process.

Some embodiments of the present invention provide CdTe photovoltaic panels with improved porosity and cell spacing and methods thereof. For example, a semi-porous CdTe layer can improve the efficiency of a CdTe solar panel. In another example, the interface between the CdS layer and the CdTe layer is preferable to be dense to avoid optical reflection due to the change of index of refraction between semiconductors and surrounding gas, but once photons have passed the CdS/CdTe junction, the reflections of a porous film are beneficial, resulting in a longer optical path length while the electrical path length to the back contact remains short. In yet another example, a porous CdTe film also allows a reduced amount of CdTe to be used in the manufacture of CdTe photovoltaic panels. In yet another example, a porous CdTe film can also provide better electrical contact between the CdTe layer and the back contact.

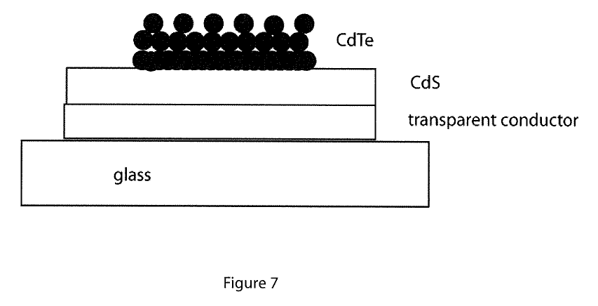

FIG. 7 is a simplified diagram showing a porous CdTe layer according to one embodiment of the present invention. This diagram is merely an example, which should not unduly limit the scope of the claims. One of ordinary skill in the art would recognize many variations, alternatives, and modifications.

For example, the porous CdTe layer has a total thickness ranging from 2 μm to 6 μm. In another example, in the sub-layer that is closest to the CdS/CdTe junction, the film porosity of the porous CdTe layer is less than 10%, but in the sub-layer that is 1-5 μm farthest from the CdS/CdTe junction, the film porosity of the porous CdTe layer ranges from 10% to 50%.

In one embodiment, the porous CdTe layer that is dense near the CdS/CdTe junction but porous far from the CdS/CdTe junction is manufactured by depositing CdTe particles in a liquid ink, drying the ink, and annealing the resulting film. In another embodiment, the porous CdTe layer that is dense near the CdS/CdTe junction but porous far from the CdS/CdTe junction is the CdTe layer 132 after completion of at least processes 101, 102, 103 and 104.

According to another embodiment, a method for making a photovoltaic device includes providing a substrate including a glass layer, a first conductive layer on the glass layer, and a cadmium sulfide layer on the first conductive layer. Additionally, the method includes depositing one or more first materials on the cadmium sulfide layer. The one or more first materials include a first quantity of chemical element cadmium and a second quantity of chemical element tellurium. Moreover, the method includes performing a first thermal treatment to at least the first quantity of chemical element cadmium, the second quantity of chemical element tellurium, and a third quantity of chemical element chlorine, so that a polycrystalline layer composed of at least cadmium telluride is formed on the cadmium sulfide layer. Also, the method includes depositing one or more second materials on a surface of the polycrystalline layer. The one or more second materials including a fourth quantity of chemical element chlorine. Additionally, the method includes performing a second thermal treatment to at least the one or more second materials so that at least a first part of the fourth quantity of chemical element chlorine diffuses into the polycrystalline layer, removing at least a second part of the fourth quantity of chemical element chlorine from the surface of the polycrystalline layer, and forming a second conductive layer on the polycrystalline layer composed of at least cadmium telluride. For example, the method is implemented according to at least FIG. 1, FIG. 2, FIG. 3, FIG. 4, and/or FIG. 5.

For example, the process for depositing one or more first materials includes depositing at least the first quantity of chemical element cadmium and the second quantity of chemical element tellurium, and depositing at least the third quantity of chemical element chlorine. In another example, the process for depositing at least the third quantity of chemical element chlorine is performed before the process for depositing at least the first quantity of chemical element cadmium and the second quantity of chemical element tellurium. In yet another example, the process for depositing at least the third quantity of chemical element chlorine is performed after the process for depositing at least the first quantity of chemical element cadmium and the second quantity of chemical element tellurium. In yet another example, the process for depositing at least the third quantity of chemical element chlorine and the process for depositing at least the first quantity of chemical element cadmium and the second quantity of chemical element tellurium overlap in time. In yet another example, the process for depositing one or more first materials includes depositing a liquid ink composed of at least one or more cadmium telluride particles and a cadmium chloride material in a solvent.

In yet another example, the process for performing a first thermal treatment includes supplying at least the third quantity of chemical element chlorine after the process for depositing one or more first materials is performed. In yet another example, the process for supplying at least the third quantity of chemical element chlorine comprises supplying a gas-phase flux of cadmium chloride. In yet another example, the process for depositing one or more first materials on the cadmium sulfide layer comprises depositing a liquid ink composed of at least one or more cadmium telluride particles suspended in a solvent, and the one or more cadmium telluride include the first quantity of chemical element cadmium and the second quantity of chemical element tellurium. In yet another example, the process for depositing one or more second materials includes depositing a liquid ink composed of at least a cadmium chloride material dissolved in a solvent, the cadmium chloride material including the fourth quantity of chemical element chlorine.

In yet another example, the first thermal treatment is performed under the atmospheric pressure at a first temperature for a first period of time, and the second thermal treatment is performed under the atmospheric pressure at a second temperature for a second period of time. In yet another example, the first temperature is higher than the second temperature, and the first period of time is longer than the second period of time. In yet another example, the process for providing a substrate comprises providing at least the first conductive layer located indirectly on the glass layer through a diffusion barrier layer, and providing at least the cadmium sulfide layer located indirectly on the first conductive layer through a buffer layer.

According to yet another embodiment, a method for making a photovoltaic device includes providing a substrate including a glass layer, a first conductive layer on the glass layer, and a cadmium sulfide layer on the first conductive layer. Additionally, the method includes depositing a first liquid ink composed of at least one or more cadmium telluride particles and a first cadmium chloride material in a first solvent, and performing a first thermal treatment to at least the one or more cadmium telluride particles and the first cadmium chloride material, so that a polycrystalline layer composed of at least cadmium telluride is formed on the cadmium sulfide layer. Moreover, the method includes depositing a second liquid ink composed of at least a second cadmium chloride material in a second solvent, and performing a second thermal treatment to at least the second cadmium chloride material so that at least a first part of the second cadmium chloride material diffuses into the polycrystalline layer. Also, the method includes removing at least a second part of the second cadmium chloride material from the surface of the polycrystalline layer, and forming a second conductive layer on the polycrystalline layer composed of at least cadmium telluride. For example, the method is implemented according to at least FIG. 1, FIG. 2, FIG. 3, FIG. 4, and/or FIG. 5.

In another example, the first thermal treatment is performed under the atmospheric pressure at a first temperature for a first period of time, and the second thermal treatment is performed under the atmospheric pressure at a second temperature for a second period of time. In yet another example, the first temperature is higher than the second temperature, and the first period of time is longer than the second period of time. In yet another example, the process for providing a substrate comprises providing at least the first conductive layer located indirectly on the glass layer through a diffusion barrier layer, and providing at least the cadmium sulfide layer located indirectly on the first conductive layer through a buffer layer. In yet another example, the first solvent and the second solvent are the same.

According to yet another embodiment, a photovoltaic device includes a substrate including a glass layer, a first conductive layer on the glass layer, and a cadmium sulfide layer on the first conductive layer. Additionally, the photovoltaic device includes a polycrystalline layer composed of at least cadmium telluride on the cadmium sulfide layer. The polycrystalline layer is doped with chemical element chlorine. Also, the photovoltaic device includes a second conductive layer on the polycrystalline layer, and an encapsulation layer on the second conductive layer. The photovoltaic device is characterized by a photovoltaic conversion efficiency that is greater than 9% under standard test conditions, an open circuit voltage that is greater than 750 mV, and a short circuit current that is greater than 20 mA/cm². For example, the device is implemented according to at least FIG. 1, FIG. 5, and/or FIG. 6. In another example, the encapsulation layer includes at least a polymer layer. In yet another example, the first conductive layer is located indirectly on the glass layer through a diffusion barrier layer, and the cadmium sulfide layer is located indirectly on the first conductive layer through a buffer layer.

According to yet another embodiment, a photovoltaic device includes a substrate including a glass layer, a first conductive layer on the glass layer, and a cadmium sulfide layer on the first conductive layer. Additionally, the photovoltaic device includes a polycrystalline layer composed of at least cadmium telluride on the cadmium sulfide layer. The polycrystalline layer is doped with chemical element chlorine. Moreover, the photovoltaic device includes a second conductive layer on the polycrystalline layer, and an encapsulation layer on the second conductive layer. The polycrystalline layer includes a first surface and a second surface, and the polycrystalline layer is characterized by a porosity. The porosity of the polycrystalline layer close to the first surface is larger than the porosity of the polycrystalline layer close to the second surface. For example, the device is implemented according to at least FIG. 1, FIG. 5, FIG. 6, and/or FIG. 7. In another example, the porosity of the polycrystalline layer close to the first surface is less than 10%, and the porosity of the polycrystalline layer close to the second surface is larger than 10% but smaller than 50%. In yet another example, the photovoltaic device is characterized by a photovoltaic conversion efficiency that is greater than 9% under standard test conditions, an open circuit voltage that is greater than 750 mV, and a short circuit current that is greater than 20 mA/cm².

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for making a photovoltaic device, the method comprising:
providing a substrate including a glass layer, a first conductive layer on the glass layer, and a cadmium sulfide layer on the first conductive layer;
depositing one or more first materials on the cadmium sulfide layer, the one or more first materials including a first quantity of chemical element cadmium and a second quantity of chemical element tellurium;
performing a first thermal treatment to at least the first quantity of chemical element cadmium, the second quantity of chemical element tellurium, and a third quantity of chemical element chlorine, so that a polycrystalline layer composed of at least cadmium telluride is formed on the cadmium sulfide layer;
depositing one or more second materials on a surface of the polycrystalline layer, the one or more second materials including a fourth quantity of chemical element chlorine;
performing a second thermal treatment to at least the one or more second materials so that at least a first part of the fourth quantity of chemical element chlorine diffuses into the polycrystalline layer;
removing at least a second part of the fourth quantity of chemical element chlorine from the surface of the polycrystalline layer; and
forming a second conductive layer on the polycrystalline layer composed of at least cadmium telluride.

2. The method of claim 1 wherein the process for depositing one or more first materials includes:
depositing at least the first quantity of chemical element cadmium and the second quantity of chemical element tellurium; and
depositing at least the third quantity of chemical element chlorine.

3. The method of claim 2 wherein the process for depositing at least the third quantity of chemical element chlorine is performed before the process for depositing at least the first quantity of chemical element cadmium and the second quantity of chemical element tellurium.

4. The method of claim 2 wherein the process for depositing at least the third quantity of chemical element chlorine is performed after the process for depositing at least the first quantity of chemical element cadmium and the second quantity of chemical element tellurium.

5. The method of claim 2 wherein the process for depositing at least the third quantity of chemical element chlorine and the process for depositing at least the first quantity of chemical element cadmium and the second quantity of chemical element tellurium overlap in time.

6. The method of claim 5 wherein the process for depositing one or more first materials includes depositing a liquid ink composed of at least one or more cadmium telluride particles and a cadmium chloride material in a solvent.

7. The method of claim 1 wherein the process for performing a first thermal treatment includes supplying at least the third quantity of chemical element chlorine after the process for depositing one or more first materials is performed.

8. The method of claim 7 wherein the process for supplying at least the third quantity of chemical element chlorine comprises supplying a gas-phase flux of cadmium chloride.

9. The method of claim 1 wherein the process for depositing one or more first materials on the cadmium sulfide layer comprises depositing a liquid ink composed of at least one or more cadmium telluride particles suspended in a solvent, the one or more cadmium telluride including the first quantity of chemical element cadmium and the second quantity of chemical element tellurium.

10. The method of claim 1 wherein the process for depositing one or more second materials includes depositing a liquid ink composed of at least a cadmium chloride material dissolved in a solvent, the cadmium chloride material including the fourth quantity of chemical element chlorine.

11. The method of claim 1 wherein:
the first thermal treatment is performed under the atmospheric pressure at a first temperature for a first period of time; and
the second thermal treatment is performed under the atmospheric pressure at a second temperature for a second period of time.

12. The method of claim 11 wherein:
the first temperature is higher than the second temperature; and
the first period of time is longer than the second period of time.

13. The method of claim 1 wherein the process for providing a substrate comprises:
providing at least the first conductive layer located indirectly on the glass layer through a diffusion barrier layer; and
providing at least the cadmium sulfide layer located indirectly on the first conductive layer through a buffer layer.

14. A method for making a photovoltaic device, the method comprising:
providing a substrate including a glass layer, a first conductive layer on the glass layer, and a cadmium sulfide layer on the first conductive layer;
depositing a first liquid ink composed of at least one or more cadmium telluride particles and a first cadmium chloride material in a first solvent;
performing a first thermal treatment to at least the one or more cadmium telluride particles and the first cadmium chloride material, so that a polycrystalline layer composed of at least cadmium telluride is formed on the cadmium sulfide layer;
depositing a second liquid ink composed of at least a second cadmium chloride material in a second solvent;
performing a second thermal treatment to at least the second cadmium chloride material so that at least a first part of the second cadmium chloride material diffuses into the polycrystalline layer;
removing at least a second part of the second cadmium chloride material from the surface of the polycrystalline layer; and
forming a second conductive layer on the polycrystalline layer composed of at least cadmium telluride.

15. The method of claim 14 wherein:
the first thermal treatment is performed under the atmospheric pressure at a first temperature for a first period of time; and
the second thermal treatment is performed under the atmospheric pressure at a second temperature for a second period of time.

16. The method of claim 15 wherein:
the first temperature is higher than the second temperature; and
the first period of time is longer than the second period of time.

17. The method of claim 14 wherein the process for providing a substrate comprises:
providing at least the first conductive layer located indirectly on the glass layer through a diffusion barrier layer; and
providing at least the cadmium sulfide layer located indirectly on the first conductive layer through a buffer layer.

18. The method of claim 14 wherein the first solvent and the second solvent are the same.

19. A photovoltaic device, the device comprising:
a substrate including a glass layer, a first conductive layer on the glass layer, and a cadmium sulfide layer on the first conductive layer;
a polycrystalline layer composed of at least cadmium telluride on the cadmium sulfide layer, the polycrystalline layer being doped with chemical element chlorine;
a second conductive layer on the polycrystalline layer; and
an encapsulation layer on the second conductive layer;
wherein the photovoltaic device is characterized by a photovoltaic conversion efficiency that is greater than 9% under standard test conditions, an open circuit voltage that is greater than 750 mV, and a short circuit current that is greater than 20 mA/cm².

20. The photovoltaic device of claim 19 wherein the encapsulation layer includes at least a polymer layer.

21. The photovoltaic device of claim 19 wherein:
the first conductive layer is located indirectly on the glass layer through a diffusion barrier layer; and
the cadmium sulfide layer is located indirectly on the first conductive layer through a buffer layer.

22. A photovoltaic device, the device comprising:
a substrate including a glass layer, a first conductive layer on the glass layer, and a cadmium sulfide layer on the first conductive layer;
a polycrystalline layer composed of at least cadmium telluride on the cadmium sulfide layer, the polycrystalline layer being doped with chemical element chlorine;
a second conductive layer on the polycrystalline layer; and
an encapsulation layer on the second conductive layer;
wherein:
the polycrystalline layer includes a first surface and a second surface;
the polycrystalline layer is characterized by a porosity;
the porosity of the polycrystalline layer close to the first surface is larger than the porosity of the polycrystalline layer close to the second surface.

23. The photovoltaic device of claim 21 wherein:
the porosity of the polycrystalline layer close to the first surface is less than 10%;
the porosity of the polycrystalline layer close to the second surface is larger than 10% but smaller than 50%.

24. The photovoltaic device of claim 21 wherein the photovoltaic device is characterized by a photovoltaic conversion efficiency that is greater than 9% under standard test conditions, an open circuit voltage that is greater than 750 mV, and a short circuit current that is greater than 20 mA/cm².
